(19) United States
(12) Patent Application Publication
(10) Pub. No.: US 2008/0079071 A1
(43) Pub. Date: Apr. 3, 2008

(54) SEMICONDUCTOR DEVICE FOR PREVENTING RECIPROCAL INFLUENCE BETWEEN NEIGHBORING GATES AND METHOD FOR MANUFACTURING THE SAME

(76) Inventor: Kyung Do KIM, Seoul (KR)

Correspondence Address: LADAS & PARRY LLP, 224 SOUTH MICHIGAN AVENUE, SUITE 1600, CHICAGO, IL, 60604, US

(21) Appl. No.: 11/681,815

(22) Filed: Mar. 5, 2007

(30) Foreign Application Priority Data
Sep. 30, 2006 (KR) 10-2006-0096720

(51) Int. Cl. H01L 29/78; H01L 21/336

(52) U.S. Cl. 257/334; 438/270; 257/E29.225; 257/E21.409

(57) ABSTRACT

A semiconductor device has a pair of gate forming areas, a drain forming area between the gate forming areas, and source forming areas outside of the gate forming areas in the active region. Recess gates are formed in the respective gate forming areas of the active region and depressed inward on the sidewalls of lower buried portions thereof formed in the substrate, which face the drain forming area, such that each of the lower buried portions has a decreased width, thereby creating an asymmetrical structure in which the distance between the lower buried portions of the recess gates is greater than the distance between upper buried portions of the recess gates. Source and drain areas formed on the surface of the substrate on both sides of the recess gates.

### CROSS-REFERENCE TO RELATED APPLICATIONS

The present application claims priority to Korean patent application number 10-2006-0096720 filed on Sep. 30, 2006, which is incorporated herein by reference in its entirety.

### BACKGROUND OF THE INVENTION

The present invention relates to a semiconductor device, and more particularly to a semiconductor device having recess gates, which increases the effective channel length and prevents the reciprocal influence between neighboring gates from decreasing the threshold voltage, and a method for manufacturing the same.

As the design rule for semiconductor devices decreases below 100 nm, the short channel effect, in which the reduction of the channel length causes the threshold voltage to abruptly decrease due to the reduction of the channel length, causes critical obstacles to proper functioning of the device. Therefore, there are inherent limitations to both the process and configuration of a semiconductor device when utilizing a conventional planar-type transistor to attain the target threshold voltage.

In order to overcome the problems caused by the short channel effect, a semiconductor device having recess gates has been disclosed in the art. In the semiconductor device having recess gates, grooves are defined on portions of a silicon substrate, and gates are subsequently formed in the grooves such that the effective channel length is increased when compared to a planar-channel structure.

Hereafter, a conventional semiconductor device having recess gates will be described with reference to FIG. 1.

Referring to FIG. 1, an isolation structure 102, which defines one boundary of an active region, is formed in a silicon substrate 100, grooves H1 are defined in the gate forming areas of the active region, and recess gates 110 are formed in the grooves H1. The recess gate 110 comprises a stack of a gate insulation layer 111, a polysilicon layer 112, a tungsten silicide layer 113, and a hardmask nitride layer 114.

Gate spacers 115 are respectively formed on both sidewalls of the recess gate 110. Source and drain areas 116 and 117 are respectively formed on the surface of the substrate 100 on both sides of the recess gate 110. Landing plugs 130 are formed in-between the recess gates 110 including the gate spacers 115, that is, on the source and drain areas 116 and 117. For example, the gate spacer 115 comprises a double layer composed of an oxide layer and a nitride layer. The reference numeral 120 designates an interlayer dielectric.

Compared to a conventional semiconductor device characterized by a planar channel structure, the recessed channel structure of the above-described semiconductor device mitigates the short channel effect.

Although the conventional semiconductor device having recess gates possesses some advantages as described above, the shortened distance between the recess gates causes problems in that an operation of one gate in a DRAM cell causes the threshold voltage of the other gate to decrease, thereby degrading the punch-through characteristic.

FIG. 2 is a graph illustrating the decrease in threshold voltage that occurs when a voltage is applied to a neighboring recess gate in the conventional semiconductor device having recess gates. Referring to FIG. 2, it can be understood that the threshold voltage of a recess gate decreases under the influence of a neighboring gate, which leads to a threshold voltage that is less than the predetermined value.

Specifically, as the design rule of a semiconductor device is decreased, the distance between recess gates decreases as the size of the cell decreases. Therefore, it is expected that the reciprocal influence between the neighboring gates will increase. Hence, in order to realize a highly integrated semiconductor device, the problems associated with the reduction of threshold voltage caused by the reciprocal influence between the neighboring gates, and resultant degradation of punch-through characteristics, must be addressed.

### SUMMARY OF THE INVENTION

An embodiment of the present invention is directed to a semiconductor device having recess gates, which prevent the threshold voltage from decreasing due to the reciprocal influence between neighboring gates, and a method for manufacturing the same.

An embodiment of the present invention is directed to a semiconductor device having recess gates, which can prevent a threshold voltage from decreasing due to the reciprocal influence between neighboring gates, thereby securing the desired punch-through characteristics, and a method for manufacturing the same.

An embodiment of the present invention is directed to a semiconductor device having recess gates, which can prevent the reciprocal influence between neighboring gates, thereby enabling the realization of a highly integrated semiconductor device having the desired characteristics, and a method for manufacturing the same.

In one embodiment, a semiconductor device comprises a silicon substrate; an isolation structure formed in the silicon substratethat delimits an active region, which has a pair of gate forming areas, a drain forming area between the gate forming areas, and source forming areas outside of the gate forming areas; recess gates formed in the respective gate forming areas of the active region that are depressed inward on the sidewalls of lower buried portions thereof formed in the substrate, which face the drain forming area, such that each of the lower buried portions has a decreased width and an asymmetrical structure is obtained in which the distance between the lower buried portions of the recess gates is greater than the distance between upper buried portions of the recess gates; and source and drain areas formed in a surface of the substrate on both sides of the recess gates.

The source and drain areas have a depth that is substantially the same as that of the upper buried portions of the recess gates, which are formed in the substrate.

The upper buried portions of the recess gates, which are formed in the substrate, have a depth of 200˜500 Å.

The semiconductor device further comprises gate spacers formed on both sidewalls of each recess gate.

The semiconductor device further comprises landing plugs formed on the source and drain areas between the recess gates including the gate spacers.

In another embodiment, a method for manufacturing a semiconductor device comprises the steps of forming an isolation structure in the silicon substrate, which delimits an active region having a pair of gate forming areas, a drain forming area between the gate forming areas, and source forming areas outside of the gate forming areas; forming a hardmask on the silicon substrate including the isolation structure, which has openings for exposing the gate forming areas; defining first grooves by etching the exposed gate forming areas; forming spacers on sidewalls of the first grooves including the openings of the hardmask, which face the drain forming area; defining second grooves under the first grooves by etching the exposed bottom portions of the first grooves using the spacers and the hardmask as an etch mask; removing the spacers and the hardmask; forming recess gates in the asymmetrical recess grooves that are composed of the first groove and the second groove; and forming source and drain areas on the surface of the substrate on both sides of the recess gates.

The hardmask is formed as a stack of an oxide layer and a polysilicon layer.

The first groove is defined to have a depth of 200˜500 Å.

The step of forming spacers comprises the sub steps of forming a spacer layer on the hardmask including the first grooves; forming spacers on both sidewalls of the first grooves including the openings of the hardmask by anisotropically etching the spacer layer; forming a photoresistant pattern on the resultant substrate that has the spacers located on both sidewalls of the first grooves including the openings of the hardmask, such that the spacers formed on the sidewalls of the first grooves facing the drain forming area are covered by the photoresistant pattern, and the spacers formed on the sidewalls of the first grooves facing the source forming areas are exposed; removing the exposed spacers that are formed on the sidewalls of the first grooves facing the source forming areas; and removing the photoresistant pattern.

The spacer layer has a thickness of 10˜400 Å.

The second groove has a depth of 200˜500 Å.

The asymmetrical recess groove composed of the first groove and the second groove has a depth of 400˜1,000 Å.

The step of forming recess gates comprises the sub steps of forming a gate insulation layer on the surface of the substrate including the asymmetrical recess grooves; forming a first gate conductive layer on the gate insulation layer to fill the asymmetrical recess grooves; planarizing the surface of the first gate conductive layer; sequentially forming a second gate conductive layer and a hardmask layer on the planarized first gate conductive layer; and etching the hardmask layer, the second gate conductive layer, the first gate conductive layer, and the gate insulation layer.

After the step of forming recess gates and before the step of forming source and drain areas, the method further comprises the step of forming gate spacers on both sidewalls of the recess gates.

The gate spacer comprises a double layer composed of an oxide layer and a nitride layer.

After the step of forming gate spacers, the method further comprises the step of forming landing plugs on the source and drain areas between the recess gates including the gate spacers.

### BRIEF DESCRIPTION OF THE DRAWINGS

FIG. 1 is a cross-sectional view illustrating a conventional semiconductor device having recess gates.

FIG. 2 is a graph illustrating that the threshold voltage decreases when a voltage is applied to a neighboring recess gate in the conventional semiconductor device having recess gates.

FIG. 3 is a cross-sectional view illustrating a semiconductor device having recess gates in accordance with an embodiment of the present invention.

FIGS. 4A through 4G are cross-sectional views illustrating the method for manufacturing a semiconductor device having recess gates in accordance with the embodiment of the present invention.

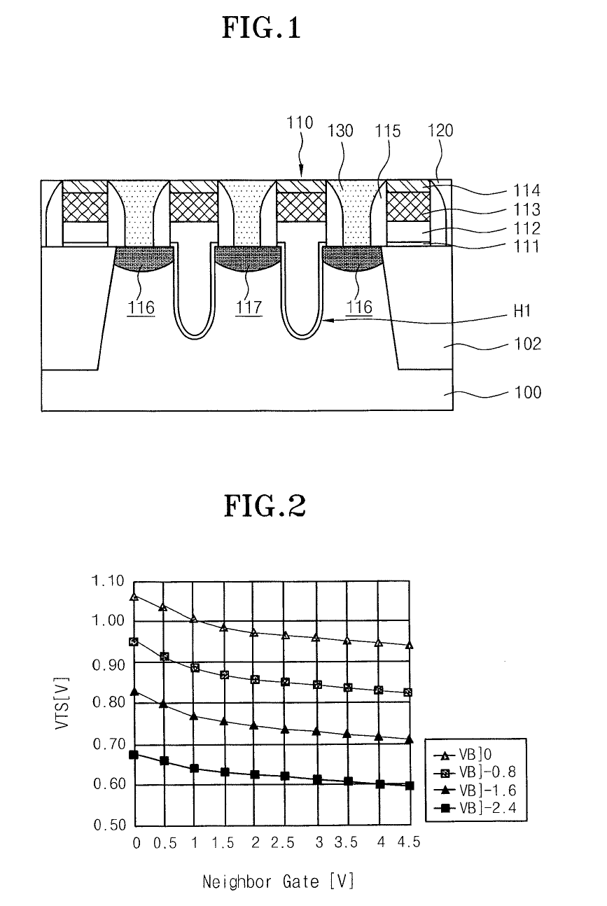

### DESCRIPTION OF SPECIFIC EMBODIMENTS

In a semiconductor device having recess gates, the reciprocal influence between recess gates in one cell is prevented to be non-existent or slight within the upper buried portions of the recess gates due to the presence of a highly doped impurity area, that is, a drain area. However, in the lower buried portions of the recess gates, the reciprocal influence between the recess gates is fairly substantial since there is no provision for preventing reciprocal influence between recess gates.

In solving the problems, an embodiment of the present invention is directed to forming a pair of recess gates in one cell such that while the upper portions of recess channels are formed in the similar manner as the conventional art, the sidewalls in the lower portions of the recess channels, which face each other, project inward into the respective recess channels, such that the width of the lower portion of each recess channel decreases by a predetermined size and the distance between the recess gates is increased, thereby preventing the reciprocal influence between the recess gates.

By doing this, source and drain areas in the upper portions of the recess channels prevent the reciprocal influence between the gates, and in the lower portions of the recess channels, the increased distance between gates prevents the occurrence of reciprocal influence between the gates. As a consequence, in an embodiment of the present invention, while the effective channel length may be increased through adoption of recess gates, a decrease in a threshold voltage due to the reciprocal influence between neighboring gates and the resultant degradation of a punch-through characteristic is prevented, whereby it is possible to realize a highly integrated semiconductor device having the desired characteristics.

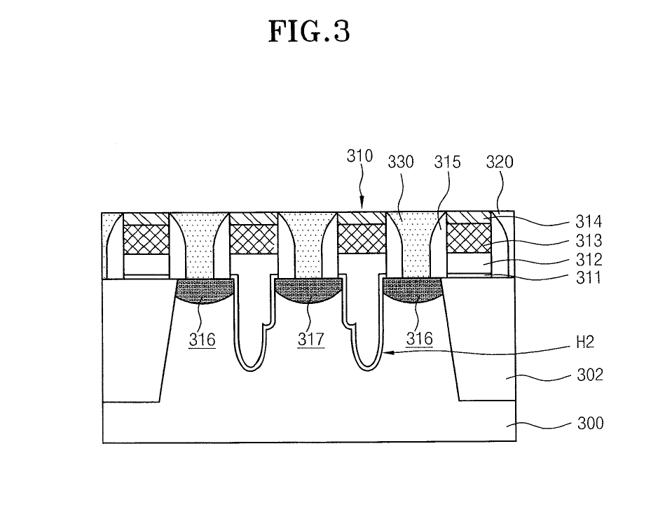

A semiconductor device having recess gates in accordance with an embodiment of the present invention will be described in detail with reference to the cross-sectional view of FIG. 3.

Referring to FIG. 3, an isolation structure 302 is formed in a silicon substrate 300. The isolation structure 302 delimits or defines one boundary adjoining an active region having: a pair of gate forming areas, a drain forming area between the gate forming areas, and source forming areas outside of the gate forming areas. Recess grooves H2 for defining recess channels are respectively defined in the gate forming areas of the active region, and recess gates 310 are respectively formed in the recess grooves H2.

Unlike the conventional recess groove in which the lower portion is symmetrical to the upper portion, the upper and lower portions of each recess groove H2 as shown according to an embodiment of FIG. 3 of the present invention are not symmetrical. That is, the sidewall of the lower portion of each recess groove H2 facing the side of a drain area 317 is formed farther away from the drain area 317 by a predetermined width as compared to the sidewall of the upper portion of each recess groove facing the side of the drain 317. Accordingly, the lower buried portion of the recess gate 310 formed in the asymmetrical recess groove H2 is also asymmetrical with respect to the upper buried portion of the recess gate 310. The recess gate 310 has a stacked configuration, and includes a gate insulation layer 311 that is formed on the surface of the recess groove H2, a polysilicon layer 312 as a first gate conductive layer that fills the recess groove H2 including the gate insulation layer 311, a tungsten silicide layer 313 as a second gate conductive layer that is formed on the polysilicon layer 312, and a hardmask layer 314 that is formed on the tungsten silicide layer 313.

Gate spacers 315, each of which comprises a double layer composed of an oxide layer and a nitride layer, are formed on both sidewalls of each recess gate 310. Source and drain areas 316 and 317 are formed on the surface of the silicon substrate 300 on both sides of the recess gates 310. Landing plugs 330 are formed on the source and drain areas 316 and 317 between the recess gates 310 including the gate spacers 315. The reference numeral 320 designates an interlayer dielectric.

Since the semiconductor device having recess gates in accordance with an embodiment of the present invention possesses a recessed channel structure, the effective channel length is increased, and the short channel effect is mitigated. Further, the sidewall of the lower buried portion of each pair of recess gates formed in one cell facing the drain area is depressed inward, resulting in a decreased width for lower buried portion as compared to the width of the upper buried portion. As a consequence, it is possible to prevent the threshold voltage from changing under the reciprocal influence between neighboring gates and also possible to prevent the leakage current characteristic from subsequently degrading. As a result, in the present invention, it is possible to realize a highly integrated semiconductor device that has the desired characteristics.

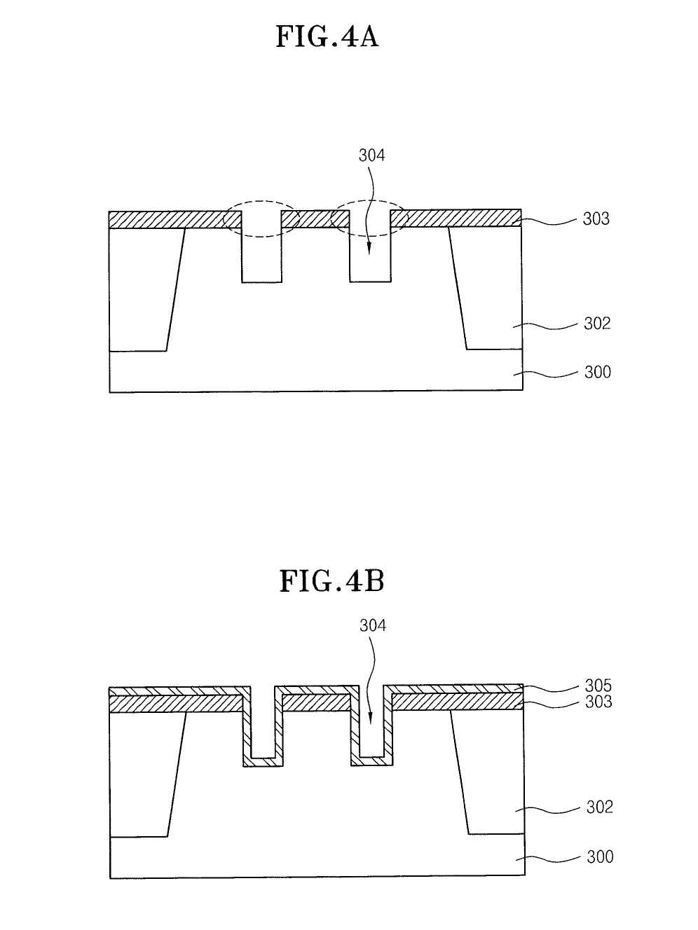

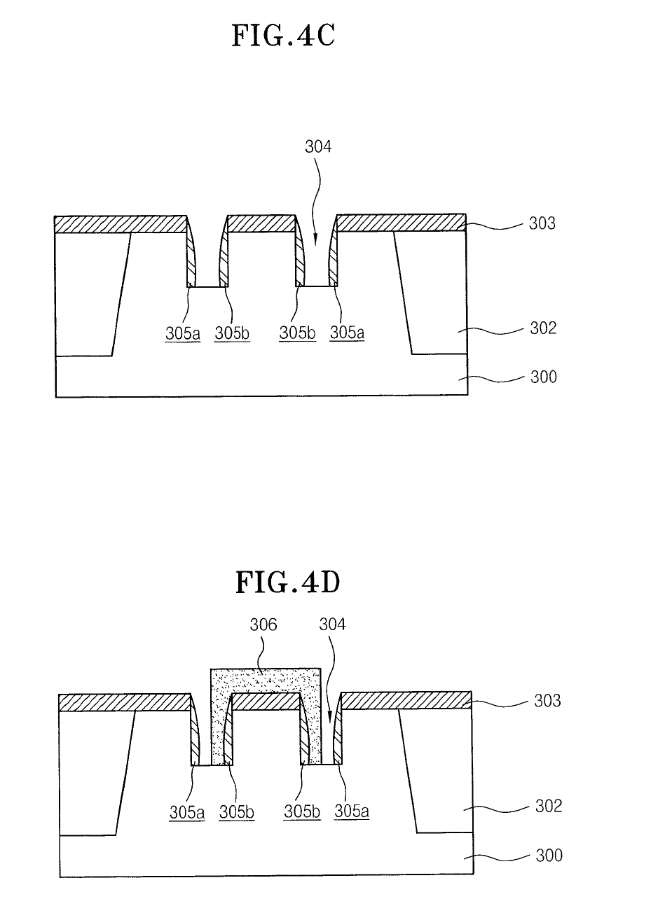

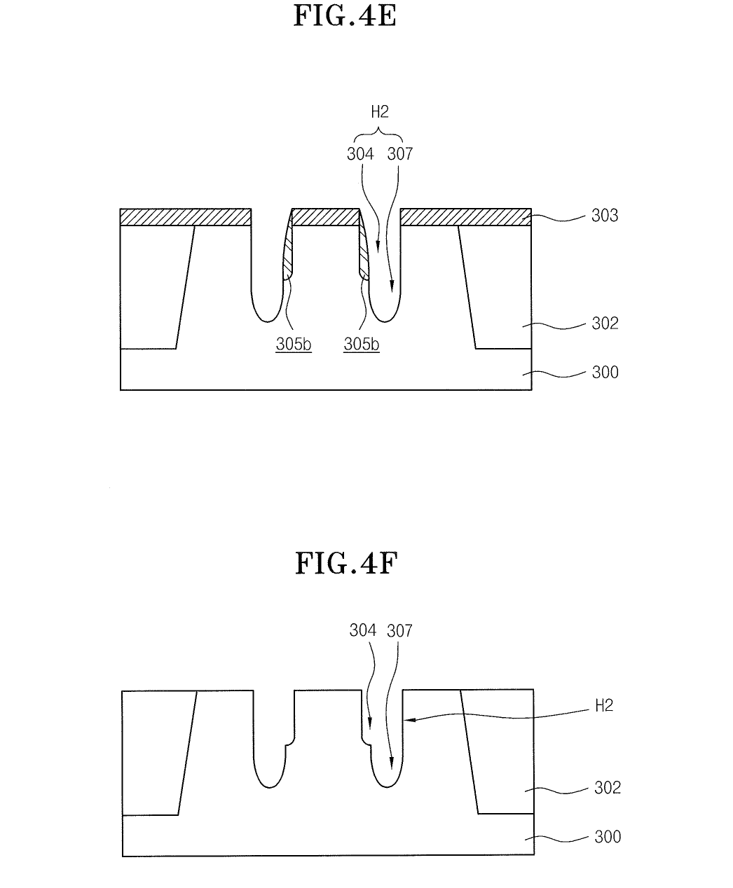

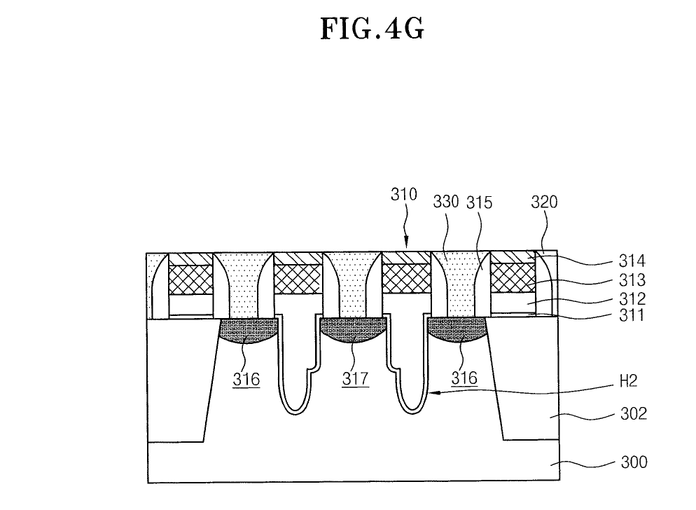

Hereafter, a method for manufacturing a semiconductor device having recess gates in accordance with another embodiment of the present invention will be described with reference to FIGS. 4A through 4G.

Referring to FIG. 4A, an isolation structure 302 is formed in a silicon substrate 300 by conducting a shallow trench isolation (STI) process to delimit an active region, which has a pair of gate forming areas, a drain forming area between the gate forming areas, and source forming areas outside of the gate forming areas. A hardmask 303 is formed on the silicon substrate 300 including the isolation structure 302 such that the hardmask 303 has openings for exposing the gate forming areas of the active region. For example, the hardmask 303 is formed as a stacked layer of an oxide layer and a polysilicon layer. First grooves 304 are defined by etching the exposed gate forming areas of the active region using the hardmask 303 as an etch mask. At this time, the first grooves 304 are defined to have a depth of 200˜500 Å.

Referring to FIG. 4B, a spacer nitride layer 305 is deposited on the hardmask 303 including the first grooves 304. The spacer nitride layer 305 is formed to have a thickness that is determined based on the desired distance between the lower portions of recess channels, for example, 10∥300 Å.

Referring to FIG. 4C, by anisotropically etching the spacer nitride layer 305, first and second spacers 305a and 305b are respectively formed on both sidewalls of the first grooves 304 including the openings of the hardmask 303. The first spacers 305a are formed on the sidewalls of the first grooves 304 that face the source forming areas, and the second spacers 305b are formed on the sidewalls of the first grooves 304 that face the drain forming area.

Referring to FIG. 4D, after a photoresist is deposited on the resultant substrate that is formed with the first and second spacers 305a and 305b, by exposing and developing the photoresist, a photoresist pattern 306 is formed such that the second spacers 305b, which are formed on the sidewalls of the first grooves 304 facing the drain forming area, are covered by the photoresist pattern 306, and the first spacers 305a, which are formed on the sidewalls of the first grooves 304 facing the source forming areas, are exposed. The first spacers 305a that are not covered by the photoresist pattern 306 are removed by wet etching.

Referring to FIG. 4E, the photoresist pattern 306 used as an etch mask is removed. The exposed lower ends of the first grooves 304 are etched using the hardmask 303 including the remaining second spacers 305b as an etch mask, and thereby, second grooves 307 are defined under the first grooves 304. In this way, recess grooves H2 composed of the first grooves 304 and the second grooves 307 are defined. In the same manner as the first grooves 304, the second grooves 307 are defined to have a depth of 200˜500 Å. Therefore, the recess grooves H2 could have a depth of 400˜1,000 Å according to an embodiment of the present invention.

Here, the sidewalls of the second grooves 307, which face the drain forming area, protrude inward such that the width of the lower portion of each second groove 307 is decreased by a predetermined size that corresponds to the width of the second spacer 305b. Therefore, the recess groove H2, which is finally defined to include the second groove 307, has an asymmetrical structure. In particular, the distance between the second grooves 307, that is, the distance between the lower portions of the recess grooves H2, increases when compared to the conventional art.

Referring to FIGS. 4E-4F, the remaining second spacers 305b are then removed. The hardmask 303 is subsequently removed to expose the resultant substrate, which has the asymmetrical recess grooves H2 defined in the gate forming areas.

Referring to FIG. 4G, a gate insulation layer 311 is formed on the surface of the resultant substrate 300 including the asymmetrical recess grooves H2. After a polysilicon layer 312 as a first gate conductive layer is deposited on the gate insulation layer 311 to fill the asymmetrical recess grooves H2, the surface of the polysilicon layer 312 is planarized by a CMP process. A metallic layer as a second conductive layer, for example, a tungsten silicide layer 313, is deposited on the planarized polysilicon layer 312, and a hardmask layer 314 comprising a nitride layer is deposited on the tungsten silicide layer 313.

After a gate mask (not shown) is formed on the hardmask layer 314, the hardmask layer 314 is etched using the gate mask. In succession, the tungsten silicide layer 313, the polysilicon layer 312 and the gate insulation layer 311 are sequentially etched, thereby forming recess gates 310 in the asymmetrical recess grooves H2. At this time, the gate mask is completely removed while the etching of the layers positioned under the gate mask proceeds. If the gate mask is not completely removed, the remaining gate mask is completely removed through a separate etching process.

Thus, since the pair of recess gates formed in one cell have a structure in which the sidewall of the lower buried portion of each facing the drain forming area is depressed inward such that the width of the lower buried portion is reduced by a predetermined amount, the distance between the lower portions of the recess channels is increased in comparison with the conventional art. Hence, in the present invention, when one gate operates in one cell, the threshold voltage of the other gate does not decrease under the influence of the operating gate, and the degradation of the punch-through characteristics is effectively prevented.

In succession, after a spacer oxide layer and a spacer nitride layer are sequentially deposited on the entire surface of the substrate 300 including the recess gates 310, by anisotropically etching the spacer oxide layer and the spacer nitride layer, gate spacers 315, each of which comprises a double layer composed of an oxide layer and a nitride layer, are formed on both sidewalls of the recess gates 310. By conducting a highly doped impurity ion implantation process for the resultant substrate 300 that is formed with the gate spacers 315, source and drain areas 316 and 317 are formed on the surface of the substrate 300 on both sides of the recess gates 310.

After an interlayer dielectric 320 is deposited on the entire surface of the resultant substrate 300 formed with the source and drain areas 316 and 317, by conducting the conventional landing plug contact (LPC) process, landing plugs 330 are formed on the source and drain areas 316 and 317 between the recess gates 310 including the gate spacers 315.

Thereafter, while not shown in the drawings, the manufacture of the semiconductor device having recess gates in accordance with the present invention is completed through a series of subsequent processes.

As is apparent from the above description, in the present invention, the lower portion of each recess channel is asymmetrically defined with respect to the upper portion thereof, such that a distance between neighboring gates that will adequately prevent the reciprocal influence can be defined between the neighboring gates. Therefore, the short channel effect is mitigated by the increase in the effective channel length, while simultaneously preventing both a change in the threshold voltage due to the reciprocal influence between the neighboring gates and the degradation of the leakage current characteristics, thereby allowing the attainment of excellent characteristics. As a consequence, in the present invention, a highly integrated semiconductor device with excellent device characteristics is realized.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor device comprising:
a silicon substrate;
an isolation structure formed in the silicon substrate, the isolation structure delimiting an active region having:
a pair of gate forming areas;
a drain forming area between the gate forming areas; and
source forming areas outside the gate forming areas;
recess gates each of which is formed in the gate forming area of the active region, each recess gate comprising: a lower buried portion and a upper buried portion in the gate forming area of the substrate,
wherein the sidewall of the lower buried portion is formed to extend farther away from the drain forming area than the sidewall of the upper buried portion such that the width of each lower buried portion is narrower than the width of the upper buried portion formed above, and
wherein the distance between the pair of the lower buried portions of the recess gates is greater than the distance between the pair of the upper buried portions of the recess gates; and
source and drain areas formed on the surface of the substrate on both sides of the recess gates.

2. The semiconductor device of claim 1, wherein the source and drain areas are formed to have a depth that is substantially the same as that of the upper buried portions of the recess gates, which are formed in the substrate.

3. The semiconductor device of claim 2, wherein the upper buried portions of the recess gates, which are formed in the substrate, have a depth of 200˜500 Å.

4. The semiconductor device of claim 1, further comprising:
gate spacers formed on both sidewalls of each recess gate.

5. The semiconductor device of claim 4, further comprising:
landing plugs formed on the source and drain areas between the recess gates including the gate spacers.

6. A method of manufacturing a semiconductor device, comprising the steps of:
forming an isolation structure in the silicon substrate, which delimits an active region having a pair of gate forming areas, a drain forming area between the gate forming areas, and source forming areas outside of the gate forming areas;
forming a hardmask on the silicon substrate including the isolation structure, which has openings for exposing the gate forming areas;
defining first grooves by etching exposed gate forming areas;
forming spacers on sidewalls of the first grooves including the openings of the hardmask, which face the drain forming area;
defining second grooves under the first grooves by etching exposed bottom portions of the first grooves using the spacers and the hardmask as an etch mask;
removing the spacers and the hardmask;
forming recess gates in the asymmetrical recess grooves, each composed of the first groove and the second groove; and
forming source and drain areas on the surface of the substrate on both sides of the recess gates.

7. The method of claim 6, wherein the hardmask is formed as a stack of an oxide layer and a polysilicon layer.

8. The method of claim 6, wherein the first groove is defined to have a depth of 200˜500 Å.

9. The method of claim 6, wherein the step of forming spacers comprises the sub steps of:
forming a spacer layer on the hardmask including the first grooves;
forming spacers on both sidewalls of the first grooves including the openings of the hardmask by anisotropically etching the spacer layer;
forming a photoresist pattern on the resultant substrate having the spacers formed on both sidewalls of the first grooves including the openings of the hardmask, such that the spacers, which are formed on sidewalls of the first grooves facing the drain forming area, are covered by the photoresist pattern, and spacers, which are formed on the sidewalls of the first grooves facing the source forming areas, are exposed;
removing the exposed spacers that are formed on the sidewalls of the first grooves facing the source forming areas; and
removing the photoresist pattern.

10. The method of claim 9, wherein the spacer layer is formed to have a thickness of 10˜400 Å.

11. The method of claim 6, wherein the second groove is defined to have a depth of 200˜500 Å.

12. The method of claim 6, wherein the asymmetrical recess groove composed of the first groove and the second groove is defined to have a depth of 400˜1,000 Å.

13. The method of claim 6, wherein the step of forming recess gates comprises the sub steps of:
forming a gate insulation layer on the surface of the substrate including the asymmetrical recess grooves;
forming a first gate conductive layer on the gate insulation layer to fill the asymmetrical recess grooves;
planarizing the surface of the first gate conductive layer;
sequentially forming a second gate conductive layer and a hardmask layer on the planarized first gate conductive layer; and
etching the hardmask layer, the second gate conductive layer, the first gate conductive layer, and the gate insulation layer.

14. The method of claim 13, after the step of forming recess gates and before the step of forming source and drain areas, further comprising the step of:
forming gate spacers on both sidewalls of the recess gates.

15. The method of claim 14, wherein the gate spacer comprises a double layer that is composed of an oxide layer and a nitride layer.

16. The method of claim 14, after the step of forming gate spacers, further comprising the step of:
forming landing plugs on the source and drain areas between the recess gates including the gate spacers.
